(19) United States
(12) Patent Application Publication
(10) Pub. No.: US 2021/0225216 A1
(43) Pub. Date: Jul. 22, 2021

(54) Touch Display Panel, Test Method Thereof and Display Device

(71) Applicants: BOE Technology Group Co., Ltd., Beijing (CN); Hefei BOE Optoelectronics Technology Co., Ltd., Hefei, Anhui (CN)

(72) Inventors: Lisen WANG, Beijing (CN); Juncai MA, Beijing (CN); Zhaozhe XU, Beijing (CN); Shiqiang HUANG, Beijing (CN); Sheng WANG, Beijing (CN)

(73) Assignees: BOE Technology Group Co., Ltd., Beijing (CN); Hefei BOE Optoelectronics Technology Co., Ltd., Hefei, Anhui (CN)

(21) Appl. No.: 16/094,160

(22) PCT Filed: Mar. 1, 2018
(86) PCT No.: PCT/CN2018/077722

§ 371 Date: Oct. 16, 2018

(30) Foreign Application Priority Data
May 9, 2017 (CN) 201710322072.1

(51) Int. Cl. G09G 3/00; G06F 3/041; G06F 3/044; G01R 31/58

(52) U.S. Cl. CPC G09G 3/006; G06F 3/0412; G06F 3/04166; G06F 3/04164; G01R 31/58; G06F 3/0443

(57) ABSTRACT

A touch display panel, a test method thereof and a display device are provided. The touch display panel includes: a base substrate, a plurality of touch electrodes in an array provided in a touch area of the base substrate, at least four test signal lines in a non-touch area of the base substrate, and a plurality of touch traces of connecting the touch electrodes and corresponding test signal lines. Each touch electrode and peripheral touch electrodes correspond to different test signal lines. The peripheral touch electrodes refer to other touch electrodes adjacent to one touch electrode and arranged along the row direction, the column direction and the diagonal direction.

### CROSS REFERENCE TO RELATED APPLICATIONS

The application claims priority to the Chinese patent application No. 201710322072.1, filed on May 9, 2017 to CNIPA, and entitled “Touch Display Panel, Test Method thereof and Display Device”, which is incorporated herein by reference in its entirety.

### TECHNICAL FIELD

Embodiments of the present disclosure relate to a touch display panel, a test method thereof and a display device.

### BACKGROUND

Touch display driver integration (TDDI) technology integrates a touch chip and a display chip into a single chip. Before the advent of TDDI technology, the system architecture will have some display noise as the display chip is separated from the touch chip. The TDDI technology will achieve better effect in the management of noise due to the realization of unified control, so the TDDI technology has strong technical advantage and market competitiveness.

### SUMMARY

Embodiments of the present disclosure provide a touch display panel, the testing method thereof and a display device.

An embodiment of the present disclosure provides a touch display panel, comprising: a base substrate, a plurality of touch electrodes in an array provided in a touch area of the base substrate, at least four test signal lines in a non-touch area of the base substrate, and a plurality of touch traces configured to connect the touch electrodes and corresponding test signal lines. Each touch electrode and peripheral touch electrodes thereof correspond to different test signal lines; and the peripheral touch electrodes refer to other touch electrodes adjacent to the touch electrode and arranged along the row direction, the column direction and the diagonal direction of the touch electrode.

In a possible implementation, in the touch display panel provided by the embodiment of the present disclosure, the at least four test signal lines is four test signal lines; and two touch electrodes, adjacent to the touch electrode, in the row direction, the column direction and the diagonal direction correspond to a same test signal line.

In a possible implementation, in the touch display panel provided by the embodiment of the present disclosure, further comprising: a plurality of metal test pads in the non-touch area and respectively connected with the test signal lines, in which each pf the metal test pads is configured to be connected with an input end of a resistance detector in the test period, and input a test signal into a corresponding test signal line.

In a possible implementation, in the touch display panel provided by the emebodiment of the present disclosure, further comprising: a plurality of switching transistors in the non-touch area, and the touch traces are respectively connected to corresponding test signal lines through the switching transistors.

In a possible implementation, in the touch display panel provided by the emebodiment of the present disclosure, further comprising: switching signal lines in the non-touch area and connected with gate electrodes of the switching transistors.

In a possible implementation, in the touch display panel provided by the emebodiment of the present disclosure, further comprising: metal pads in the non-touch area and respectively connected with the touch traces, in which the metal pads are provided respectively between the switching transistors and corresponding touch electrodes and configured to connect touch detection chips, respectively.

In a possible implementation, in the touch display panel provided by the emebodiment of the present disclosure, the touch electrodes and the touch traces are arranged in different layers; and the touch electrodes are connected with corresponding touch traces via through holes, respectively.

In a possible implementation, in the touch display panel provided by the emebodiment of the present disclosure, the touch electrodes are multiplexed as common electrodes, respectively.

An embodiment of the present disclosure also provides a test method of the touch display panel, comprising: detecting a resistance between any two test signal lines; and determining whether the detected resistance is less than a default threshold, and if so, determining a short circuit presents between two touch electrodes or between two touch traces connected with the two test signal lines of which the resistance is less than the default threshold.

In a possible implementation, in the test method provided by the emebodiment of the present disclosure, further comprising: inputting a same test signal into the test signal lines before or after detecting the resistance between any two test signal lines; and detecting whether a display brightness at a position of each touch electrode is abnormal, and if so, determining an open circuit presents on the touch trace corresponding to the abnormal display position.

In a possible implementation, in the test method provided by the emebodiment of the present disclosure, the touch display panel further includes a plurality of switching transistors in the non-touch area; the touch traces are respectively connected to corresponding test signal lines through the switching transistors; and further comprising: switching on the switching transistors respectively before detecting the resistance between any two test signal lines and inputting a same test signal into the test signal lines, so that the touch traces can be connected with corresponding test signal lines, respectively.

In a possible implementation, in the test method provided by the emebodiment of the present disclosure, the touch display panel further includes: switching signal lines in the non-touch area and connected with the gate electrodes of the switching transistors, respectively; and switching on the switching transistors includes inputting ‘on’ signals into the switching signal lines, respectively.

An embodiment of the present disclosure also provides a test method of the touch display panel, comprising: inputting a same test signal into the test signal lines; and detecting whether a display brightness at the position of each touch electrode is abnormal, and if so, determining an open circuit presents on the touch trace corresponding to the abnormal display position.

An embodiment of the present disclosure also provides a display device, comprising: the touch display panel.

### BRIEF DESCRIPTION OF THE DRAWINGS

Embodiments of the present disclosure will be described in more detail below with reference to accompanying drawings to allow an ordinary skill in the art to more clearly understand embodiments of the present disclosure, in which:

FIG. 1a is a schematically structural view I of a touch display panel provided by an embodiment of the present disclosure;

FIG. 1b is a schematically structural view II of the touch display panel provided by an embodiment of the present disclosure;

FIGS. 2a and 2b are schematic diagrams illustrating the distribution of touch electrodes in an embodiment of the present disclosure;

FIG. 3 is a schematically structural view III of the touch display panel provided by an embodiment of the present disclosure;

FIG. 4 is a flowchart I of a test method of the touch display panel provided by an embodiment of the present disclosure; and

FIG. 5 is a flowchart II of a test method of the touch display panel provided by an embodiment of the present disclosure.

### DETAILED DESCRIPTION

Technical solutions of the embodiments will be described in a clearly and fully understandable way in connection with the drawings related to the embodiments of the disclosure. It is apparent that the described embodiments are just a part but not all of the embodiments of the disclosure. Based on the described embodiments herein, those skilled in the art can obtain other embodiment(s), without any creative work, which shall be within the scope of the disclosure.

In a touch display panel adopting TDDI technology, a common electrode layer is divided into a plurality of touch units, and by adoption of time-sharing multiplexing, that is, in the display period, the touch units are act as common electrodes and configured to provide a common voltage (Vcom), and in the touch period, the touch units act as touch electrodes and configured to provide touch capacitance signals, so as to achieve the touch and display integration effect. In the manufacturing process of the touch display panel, usually, a substrate is manufactured at first and then a driver IC and a printed circuit board (PCB) are pressed together. In the process of manufacturing the substrate, the display effect in this stage is tested, and meanwhile, touch electrodes and touch traces (Tx) connected with the touch units are also required for test, or else, if a poor touch is detected in the next manufacturing stage, materials, such as the bonded chip and the PCB will be wasted, an unnecessary production cost is added.

In the process of testing the touch display panel, due to the large number of the touch units, bonding pins connected with the touch units are densely packed, and before the module process, an electrical signal detector cannot be used to respectively test the electrical properties of each pin. Generally, all of the Tx traces of the touch units are connected together through switches; in the process of image detection, Vcom signals are supplied in a unified form; and if a Tx trace is open, the touch display panel will have chessboard squares and achieve poor display. However, the method can only detect the open-circuit of the Tx trace or the touch unit and cannot detect the short-circuit of the Tx trace or the touch unit. If the short circuit of the Tx trace or the touch unit cannot be detected, materials, such as the bonded chip and the PCB will also be wasted, an unnecessary production cost is added.

Detailed description will be given below to the preferred embodiments of the touch display panel, the test method and the display device, provided by embodiments of the present disclosure, with reference to the accompanying drawings. The size and the shape of components in the accompanying drawings do not reflect the true scale and are only intended to illustrate the content of the present disclosure.

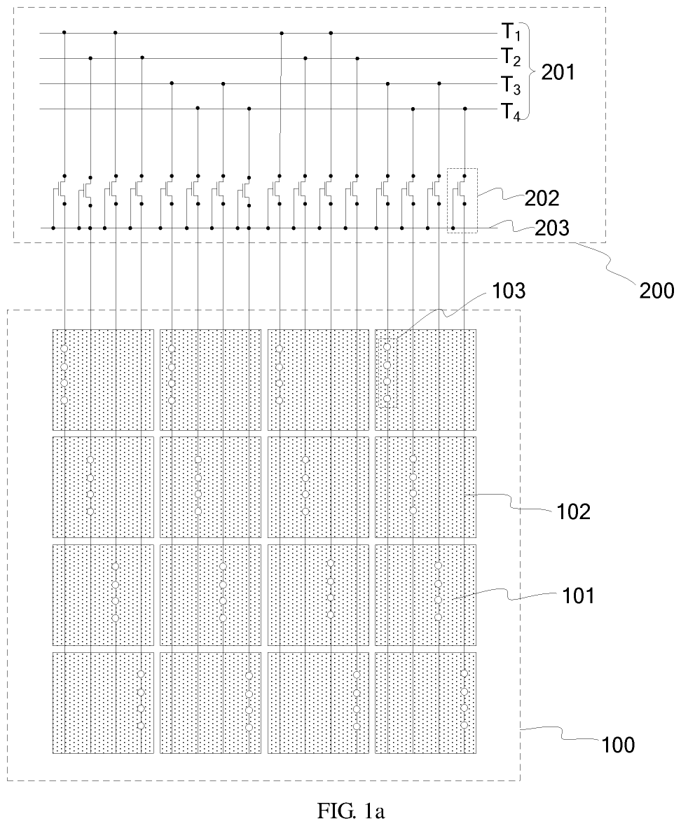

An embodiment of the present disclosure provides a touch display panel, which, as shown in FIGS. 1a and 1b, comprises: a base substrate, a plurality of touch electrodes 101 arranged in an array disposed in a touch area 100 of the base substrate, at least four test signal lines 201 disposed in a non-touch area 200 of the base substrate, and a plurality of touch traces 102 for connecting the touch electrodes 101 and corresponding test signal lines 201.

Each touch electrode 101 and the touch electrodes 101 at the periphery thereof correspond to different test signal lines 201.

The peripheral touch electrodes 101 refer to other touch electrodes 101 adjacent to one touch electrode 101 and arranged along the row direction, the column direction and the diagonal direction.

In the touch display panel provided by the embodiment of the present disclosure, at least four test signal lines 201 are disposed in the non-touch area 200, and one touch electrode 101 and the peripheral touch electrodes 101 correspond to different test signal lines 201, so whether the touch electrode 101 or the touch trace 102 is shorted can be subsequently determined by detecting the resistance between any two test signal lines 201.

In an example, the touch display panel may be a liquid crystal display (LCD) panel or an organic light-emitting diode (OLED) display panel and may also be a display panel of other types. In the touch area 100 of the touch display panel, the touch electrodes 101 arranged in an array may be arranged in any layer in the touch display panel and may also partially or entirely utilize electrodes in the touch display panel. For instance, when the touch display panel is an LCD panel, common electrodes may be multiplexed as the touch electrodes 101, namely the common electrode is divided into a plurality of sub-electrodes which correspond to pixel units, and the sub-electrodes are subjected to time-sharing driving and act as the common electrodes in the display period, and act as the touch electrodes 101 in the touch period. In an example, the touch electrodes 101 may be independently arranged in a layer, however, the embodiment of the present disclosure is not limited thereto.

Description is given in FIG. 1a by taking the arrangement of four rows and four columns of touch electrodes and the arrangement of four test signal lines (T₁, T₂, T₃ and T₄) as an example. More touch electrodes and more test signal lines may be included, not limited to the number of the touch electrodes and the test signal lines in the above example. For instance, as shown in FIG. 1b, five test signal lines (T₁, T₂, T₃, T₄ and T₅) may be arranged. FIG. 1b only illustrates one connection mode of including five test signal lines 201. In an example, other connection modes may also be adopted when five test signal lines 201 are included, and will not be listed here one by one. The touch electrodes 101 are connected with corresponding test signal lines 201 through the touch traces 102, and the touch electrode 101 and the peripheral touch electrodes 101 correspond to different test signal lines 201, in which the peripheral touch electrodes 101 refer to touch electrodes 101 adjacent to the touch electrode 101 and arranged along the row direction, the column direction and the diagonal direction. As shown in FIGS. 1a and 1b, each touch electrode 101 and its peripheral touch electrodes 101 have different corresponding test signal lines 201, respectively. When the touch display panel is subjected to electrical signal detection, the resistance between any two test signal lines 201 is detected through a resistance detector. In normal condition, there is no electrical signal connection between the test signal lines 201, namely the resistance between any two test signal lines 201 is infinity; and if there is a short circuit between the touch electrodes 101 or between the touch traces 102 connected with the two test signal lines 201, the resistance between the two test signal lines 201 is not infinitely great again. So, by setting a default threshold, e.g., 100 kΩ, when the resistance between the two test signal lines 201 is detected to be less than the default threshold, a short circuit is determined to present between the touch electrodes 101 or between the touch traces 102 connected with the two testing signal lines 201. In this way, the touch display panel having a short circuit can be intercepted, so the touch display panel will not enter the subsequent process, and resource waste can be avoided.

For instance, during the electrical signal detection on the touch display panel, whether the touch trace 102 in the touch display panel is open may also be detected. For instance, a same test signal may be inputted into the test signal lines 201, for example, a same common voltage (Vcom) signal is inputted. As the test signals inputted into the test signal lines 201 are the same, the display brightness at positions of the touch electrodes 101 shall be roughly the same. If the touch trace 102 corresponding to certain touch electrode 101 is open, the display brightness at the position of the touch electrode 101 will be abnormal, so whether the touch trace 102 is open may be detected by detecting whether the display brightness at the position of the touch electrode 101 is abnormal. In this way, the touch display panel having an open circuit can be intercepted, so the touch display panel cannot enter the subsequent process again, and resource waste can be avoided.

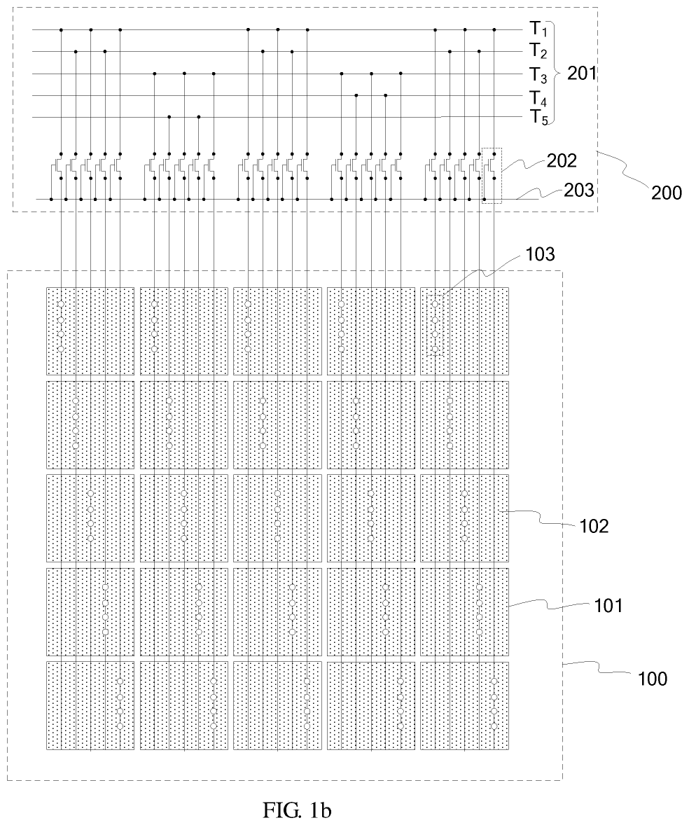

As shown in FIGS. 2a and 2b, only the touch electrodes 101 are shown in the figure for more clear illustration of the corresponding relationship between the touch electrodes 101 and the test signal lines 201, in which different filling patterns are adopted to represent corresponding different test signal lines 201. For instance, if filling patterns of a touch electrode A₁ and a touch electrode A₂ are different, test signal lines 201 connected with both are different. In FIG. 2a, the touch display panel comprises four test signal lines 201. As shown in the figure, the filling patterns of the touch electrode 101 and the peripheral touch electrodes 101 are all different. For example, for the touch electrode A₄ in the second row and the second column, a touch electrode 101 adjacent to this touch electrode 101 in the row direction is A₂, a touch electrode 101 adjacent in the column direction is A₃, and a touch electrode 101 adjacent in the diagonal direction is A₁. In this way, when the touch electrode A₄ is connected with the peripheral touch electrodes 101 (namely shorted), the short circuit may be detected by detecting the resistance between the test signal lines 201 connected with the two touch electrodes 101. In FIG. 2b, the touch display panel only comprises three test signal lines 201, which cannot ensure that the test signal lines 201 corresponding to the touch electrode 101 and its peripheral touch electrodes 101 are all different. As shown in FIG. 2b, corresponding test signal lines 201 of each touch electrode 101 and the touch electrode 101 adjacent in the diagonal direction are the same. That is to say, when two touch electrodes 101 adjacent in the diagonal direction are shorted, corresponding test signal lines 201 are the same, so the resistance between any two test signal lines 201 does not change. In this way, when only three test signal lines 201 are included, not all the short circuit conditions can be detected, so there is missed detection. In this way, the touch display panel shall at least comprise four test signal lines 201.

For instance, in the touch display panel provided by the embodiment of the present disclosure, as shown in FIG. 2a, the number of the test signal lines 201, for instance, is four.

In the row direction, the column direction and the diagonal direction, two touch electrodes 101 adjacent to the touch electrode 101 correspond to a same test signal line 201. For instance, the touch electrode in the second row and the second column in FIG. 2a is A₄, the touch electrodes 101 adjacent in the row direction are all A₂, the touch electrodes 101 adjacent in the column direction are all A₃, and the touch electrodes 101 adjacent in the diagonal direction are all A₁.

Based on the above analysis, the number of the test signal lines 201 is at least four. When the number of the test signal lines 201 is four, on the one hand, it can be ensured that all the short-circuit conditions can be detected, so as to avoid the missed detection of the short-circuit conditions; in addition, when the number of the test signal lines 201 used in the case of being able to detect all the short circuits is minimum, in the process of electrical signal detection, the resistance between any two test signal lines 201 needed to be detected. When the number of the test signal lines 201 is set to be four, in the process of electrical signal detection, the resistance between any two test signal lines 201 can be obtained only by test for six times, so the detection time is the shortest, and the cost can be saved.

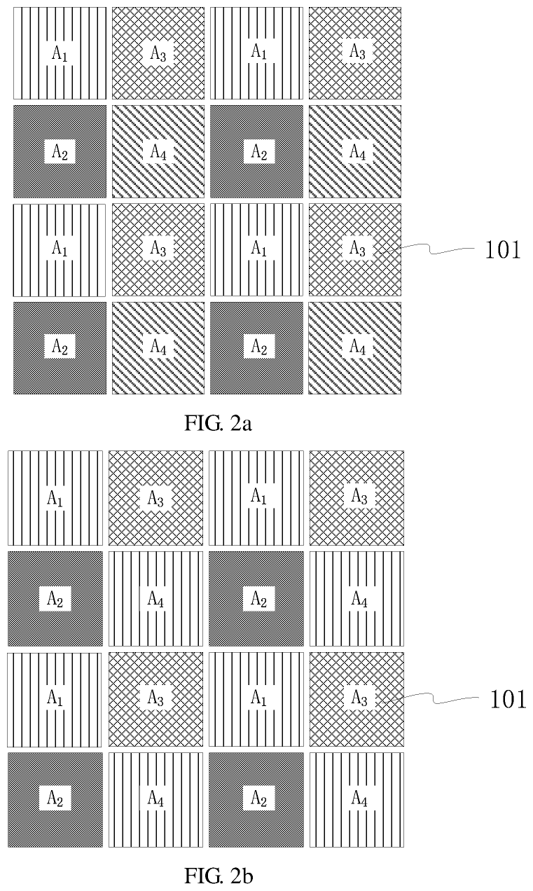

Moreover, for instance, the touch display panel provided by an embodiment of the present disclosure, as shown in FIG. 3, may also comprise: a plurality of metal test pads 204 disposed in the non-touch area 200 and respectively connected with the test signal lines 201.

The metal test pad 204 is configured to be connected with an input end of a resistance detector 300 in the test period, and input a test signal into corresponding test signal line 201.

By arrangement of the metal test pads 204 connected with the test signal lines 201, as the width of the metal test pad 204 is generally much greater than the width of the test signal line 201, in the test period, the resistance detector 300 is electrically connected with the test signal line 201 through the metal test pad 204. Compared with the case that the resistance detector 300 is directly connected with the test signal line 201, the operation is more convenient, and error test, due to poor connection between the resistance detector 300 and the test signal line 201, can also be avoided. Similarly, in the process of detecting an open circuit, test signals are inputted into the test signal lines 201 through the metal test pads 204, which is also relatively easier to operate.

As shown in FIGS. 1a, 1b and 3, the touch display panel provided by an embodiment of the present disclosure may also comprise: a plurality of switching transistors 202 disposed in the non-touch area 200.

The touch traces 102 are respectively connected to corresponding test signal lines 201 through the switching transistors 202.

For instance, source electrodes (or drain electrodes) of the switching transistors 202 may be connected with the touch traces 102, and drain electrodes (or source electrodes) are connected with corresponding test signal lines 201. In the test period, before the short-circuit or the open-circuit detection, a high level is applied to the switching transistors 202, so that the touch traces 102 can be connected with corresponding test signal lines 201; and after the short-circuit or the open-circuit detection, a low level is applied to the switching transistors 202, so that the touch traces 102 can be disconnected from corresponding test signal lines 201, which can prevent the test signal lines 201 from affecting the display or touch detection effect of the touch display panel in the display period or the touch period.

Moreover, for instance, the touch display panel provided by an embodiment of the present disclosure may also comprise: switching signal lines 203 disposed in the non-touch area 200 and connected with gate electrodes of the switching transistors 202.

As the switching transistors 202 can be simultaneously switched on and off, the switching signal lines 203 may be configured to be connected with the switching transistors 202. In this way, in the test period, before the short-circuit or the open-circuit detection, the touch traces 102 are connected with corresponding test signal lines 201 by applying a high level to the switching signal lines 203; and after the short-circuit or the open-circuit detection, the touch traces 102 are disconnected from corresponding test signal lines 201 by applying a low level to the switching signal lines 203, which can avoid the operation of the switching transistors 202 one by one and making the operation more convenient.

Moreover, for instance, the touch display panel provided by an embodiment of the present disclosure, as shown in FIG. 3, may also comprise: metal pads 205 disposed in the non-touch area 200 and respectively connected with the touch traces 102.

The metal pad 205 is disposed between the switching transistor 202 and corresponding touch electrode 101 and connected with a touch detection chip.

Only the touch display panel that has not been detected to have a short circuit or an open circuit in the test period is bound with a touch detection chip, and the metal pad 205 bonded with the touch detection chip is reserved, as shown in FIG. 3. For instance, the metal pads 205 may also be in different layers with the touch traces 102. At this point, a plurality of through holes 206 for connecting the metal pads 205 and corresponding touch traces 102 may be formed, and one metal pad 205, for instance, may correspond to a plurality of through holes 206, which can avoid an open circuit due to poor contact. The touch detection chip may be a chip only having touch detection function, or may be a chip integrating touch detection and display driving. The embodiment of the present disclosure is not limited thereto.

For instance, in the touch display panel provided by the embodiments of the present disclosure, as shown in FIGS. 1a, 1b and 3, the touch electrodes 101 and the touch traces 102 are arranged in different layers.

The touch electrodes 101 are connected with corresponding touch traces 102 via through holes 103.

In the figure, a circle on the touch trace 102 represents the through hole 103, and one touch electrode 101 generally corresponds to a plurality of through holes 103 and is connected with the touch trace 102, which can avoid the open circuit between the touch electrode 101 and corresponding touch trace 102 due to poor contact.

For instance, in the touch display panel provided by an embodiment of the present disclosure, the touch electrodes 101 are multiplexed as common electrodes, namely a common electrode layer is divided into a plurality of sub-electrodes which correspond to pixel units, respectively, and the sub-electrodes are subjected to time-sharing driving and act as the common electrodes in the display period and act as the touch electrodes 101 in the touch period, so that the touch electrodes 101 can be multiplexed as the common electrodes. The touch electrodes 101, for instance, are self-capacitance electrodes, or may be touch sensing electrodes or touch driving electrodes in mutual-capacitance electrodes, and the embodiment of the present disclosure is not limited thereto.

Based on the same concept, an embodiment of the present disclosure also provides a test method of the above touch display panel. As the principle of solving problems of this test method is similar to that of the above touch display panel, the implementation of the test method may refer to the implementation of the above touch display panel. No further description will be given here.

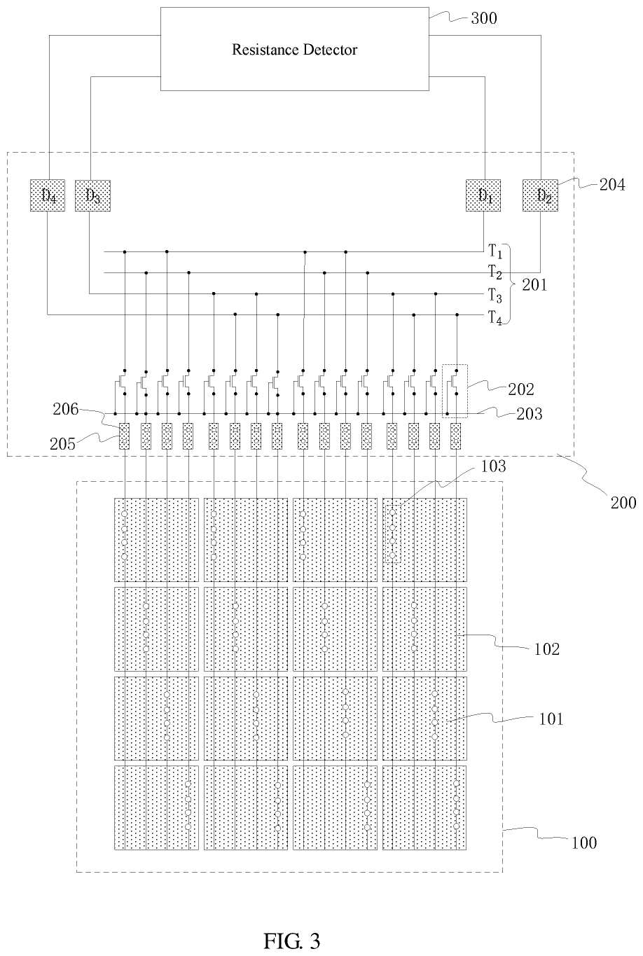

The embodiment of the present disclosure also provides a test method of the above touch display panel, which, as shown in FIG. 4, comprises:

S401: detecting the resistance between any two test signal lines; and

S402: determining whether the detected resistance is less than a default threshold, and if so, determining a short circuit presents between two touch electrodes or between two touch traces connected with the two test signal lines of which the resistance is less than the default threshold.

As shown in FIG. 3, in the operation S401, the resistance between any two test signal lines 201 may be detected by a resistance detector 300. For instance, the resistance detector 300 may detect the resistance between any two test signal lines 201. Metal test pads 204 may be connected with input ends of the resistance detector 300. As shown in FIG. 3, in normal condition, no electrical signal connection is provided between the test signal lines 201, namely the resistance between any two test signal lines 201 is infinitely great; and if a short circuit presents between the touch electrodes 101 or between the touch traces 102 connected with the two test signal lines 201, the resistance between the two test signal lines 201 is not infinitely great again. In this way, in the operation S402, by setting a default threshold, e.g., 100 kΩ, whether the detected resistance is less than the default threshold is determined; if so, a short circuit presents between the touch electrodes 101 or between the touch traces 102 connected with corresponding two test signal lines 201, so the touch display panel is unqualified; and if not, no short circuit presents on the touch display panel. In an example, the functions of the operation S402 may be also integrated into the resistance detector 300. When the detected resistance is less than the default threshold, the resistance detector 300 may prompt an operator by an alarm that the touch display panel is unqualified. A controller (e.g., a computer or other devices having data processing functions) may be adopted to collect the resistance measured by the resistance detector 300, and compare the obtained resistance with the default threshold. In this way, the touch display panel in the short-circuit condition can be intercepted, so the touch display panel does not enter the subsequent process, and the resource waste can be avoided.

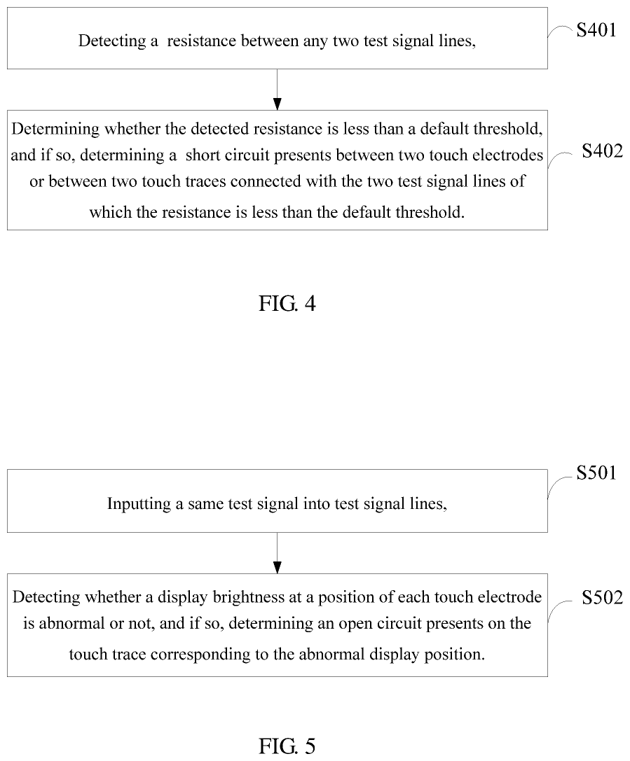

Moreover, for instance, the test method provided by an embodiment of the present disclosure, as shown in FIG. 5, may also comprise: before or after the operation S401,

S501: inputting a same test signal into the test signal lines; and

S502: detecting whether the display brightness at a position of each touch electrode is abnormal or not, and if so, determining an open circuit presents on the touch trace corresponding to the abnormal display position.

As shown in FIG. 3, in the operation S501, a same test signal may be inputted into corresponding test signal lines 201 through the metal test pads 204. As the test signals inputted into the test signal lines 201 are the same, for instance, same common voltage (Vcom) signals are inputted; in normal condition, the display brightness at the positions of the touch electrodes 101 is roughly the same, and if an open circuit presents on the touch trace 102 corresponding to certain touch electrode 101, the display brightness at the position of the touch electrode 101 will be abnormal. In this way, in the operation S502, whether the touch trace 102 is open may be determined by detecting whether the display brightness at the position of each touch electrode 101 is abnormal. In this way, the touch display panel having an open circuit can be intercepted, so that the touch display panel does not enter the subsequent process, and the resource waste can be avoided.

The test method provided the embodiment of the present disclosure can determine whether the touch electrode or the touch trace is shorted and can also determine whether the touch trace is open. The operation S501 may be executed before the operation S401 and may also be executed after the operation S401. The sequence of short-circuit detection and open-circuit detection is not limited here.

As shown in FIGS. 1a, 1b and 3, for instance, the touch display panel may also comprise a plurality of switching transistors 202 disposed in the non-touch area 100, and the touch traces 102 are respectively connected to corresponding test signal lines 201 through the switching transistors 202.

Before the operations S401 and S501, the test method may also comprise: switching on the switching transistors, so that the touch traces can be connected with corresponding test signal lines.

For instance, a high level may be applied to the gate electrodes of the switching transistors 202, so that the touch traces 102 can be connected with corresponding test signal lines 201; and after the operations S402 and S502, a low level is applied to the switching transistors 202, so that the touch traces 102 can be disconnected from corresponding test signal lines 202, which can avoid the test signal lines 201 from affecting the display or touch detection effect of the touch display panel in the display period or the touch period.

See also FIGS. 1a, 1b and 3, in an example, the touch display panel may also comprise: switching signal lines 203 disposed in the non-touch area 200 and connected with the gate electrodes of the switching transistors 202.

The operation of switching on the switching transistors, for instance, includes: inputting on signals into the switching signal lines.

For instance, the touch traces 102 can be connected with corresponding test signal lines 201 by applying a high level to the switching signal lines 203; and after the short-circuit or the open-circuit detection, the touch traces 102 are disconnected from corresponding test signal lines 201 by applying a low level to the switching signal lines 203, which can avoid the operation of the switching transistors 202 one by one and making the operation more convenient.

Based on the same concept, an embodiment of the present disclosure also provides another test method of the above touch display panel. As the principle of solving problems of this test method is similar to that of the above touch display panel, the implementation of the test method may refer to the implementation of the above touch display panel. No further description will be given here.

The embodiment of the present disclosure provides another test method of the above touch display panel, which comprises: inputting a same test signal into the test signal lines; and detecting whether the display brightness at a position of each touch electrode is abnormal, and if so, determining an open circuit presents on the touch trace corresponding to the abnormal display position.

The test method provided by the embodiment is similar to that of the test method as shown in FIG. 5. The difference is that the test method provided by the embodiment can utilize the above touch display panel to independently detect whether a short circuit presents, or not. No further description will be given to the repeated parts in the embodiment as shown in FIG. 5.

Based on the same concept, the embodiment of the present disclosure also provides a display device, which comprises the above touch display panel. The display device may be any product or component with display function, such as a mobile phone, a tablet PC, a TV, a display, a notebook computer, a digital album or a navigator. As the principle of solving problems of the display device is similar to that of the touch display panel, the implementation of the display device may refer to the implementation of the touch display panel. No description will be given to the repeated parts.

In the touch display panel, the test method thereof and the display device provided by the embodiment of the present disclosure, at least four test signal lines are arranged in the non-touch area, and the touch electrodes and the peripheral touch electrodes correspond to different test signal lines, so whether the touch electrodes or the touch traces are shorted may be subsequently determined by detecting the resistance between any two test signal lines. In addition, whether the touch traces are open may also be determined by inputting a same test signal into the test signal lines and detecting whether the display brightness at the position of each touch electrode is abnormal. In this way, the touch display panel having the short-circuit or the open-circuit can be intercepted, so that the touch display panel does not enter the subsequent process, and the process yield in the module stage can be improved and the resource waste can be avoided.

The foregoing is only the exemplary embodiments adopted for illustration of the principles of the present disclosure, but the embodiments of the present disclosure are not limited thereto. Various variations and improvements may be made by one of ordinary skill in the art without departing from the spirit and the principle of the embodiments of the present disclosure. These variations and improvements shall also fall within the scope of protection of the present disclosure.

1. A touch display panel, comprising: a base substrate, a plurality of touch electrodes in an array provided in a touch area of the base substrate, at least four test signal lines in a non-touch area of the base substrate, and a plurality of touch traces configured to connect the touch electrodes and corresponding test signal lines, wherein
each touch electrode and peripheral touch electrodes thereof correspond to different test signal lines; and
the peripheral touch electrodes refer to other touch electrodes adjacent to the touch electrode and arranged along the row direction, the column direction and the diagonal direction of the touch electrode.

2. The touch display panel according to claim 1, wherein the at least four test signal lines is four test signal lines; and
two touch electrodes, adjacent to the touch electrode, in the row direction, the column direction and the diagonal direction correspond to a same test signal line.

3. The touch display panel according to claim 1, further comprising: a plurality of metal test pads in the non-touch area and respectively connected with the test signal lines, in which each pf the metal test pads is configured to be connected with an input end of a resistance detector in the test period, and input a test signal into a corresponding test signal line.

4. The touch display panel according to claim 1, further comprising: a plurality of switching transistors in the non-touch area, in which the touch traces are respectively connected to corresponding test signal lines through the switching transistors.

5. The touch display panel according to claim 4, further comprising: switching signal lines in the non-touch area and connected with gate electrodes of the switching transistors.

6. The touch display panel according to claim 4, further comprising: metal pads in the non-touch area and respectively connected with the touch traces, in which the metal pads are provided respectively between the switching transistors and corresponding touch electrodes and configured to connect touch detection chips, respectively.

7. The touch display panel according to claim 1, wherein the touch electrodes and the touch traces are arranged in different layers; and
the touch electrodes are connected with corresponding touch traces via through holes, respectively.

8. The touch display panel according to claim 1, wherein the touch electrodes are multiplexed as common electrodes, respectively.

9. A test method of the touch display panel according to claim 1, comprising:
detecting a resistance between any two test signal lines; and
determining whether the detected resistance is less than a default threshold, and if so, determining a short circuit presents between two touch electrodes or between two touch traces connected with the two test signal lines of which the resistance is less than the default threshold.

10. The test method according to claim 9, further comprising:
inputting a same test signal into the test signal lines before or after detecting the resistance between any two test signal lines; and
detecting whether a display brightness at a position of each touch electrode is abnormal, and if so, determining an open circuit presents on the touch trace corresponding to the abnormal display position.

11. The test method according to claim 9, wherein the touch display panel further includes a plurality of switching transistors in the non-touch area; the touch traces are respectively connected to corresponding test signal lines through the switching transistors; and
the method further comprises: switching on the switching transistors respectively before detecting the resistance between any two test signal lines and inputting a same test signal into the test signal lines, so that the touch traces can be connected with corresponding test signal lines, respectively.

12. The test method according to claim 11, wherein the touch display panel further includes: switching signal lines in the non-touch area and connected with the gate electrodes of the switching transistors, respectively; and
switching on the switching transistors includes:
inputting ‘on’ signals into the switching signal lines, respectively.

13. A test method of the touch display panel according to claim 1, comprising:
inputting a same test signal into the test signal lines; and
detecting whether a display brightness at a position of each touch electrode is abnormal, and if so, determining an open circuit presents on the touch trace corresponding to the abnormal display position.

14. A display device, comprising: the touch display panel according to claim 1.

15. The touch display panel according to claim 2, further comprising: a plurality of metal test pads in the non-touch area and respectively connected with the test signal lines, in which each pf the metal test pads is configured to be connected with an input end of a resistance detector in the test period, and input a test signal into a corresponding test signal line.

16. The touch display panel according to claim 3, further comprising: a plurality of switching transistors in the non-touch area, in which the touch traces are respectively connected to corresponding test signal lines through the switching transistors.

17. The touch display panel according to claim 16, further comprising: switching signal lines in the non-touch area and connected with gate electrodes of the switching transistors.

18. The touch display panel according to claim 17, further comprising: metal pads in the non-touch area and respectively connected with the touch traces, in which the metal pads are provided respectively between the switching transistors and corresponding touch electrodes and configured to connect touch detection chips, respectively.

19. The touch display panel according to claim 18, wherein the touch electrodes and the touch traces are arranged in different layers; and
the touch electrodes are connected with corresponding touch traces via through holes, respectively.

20. The touch display panel according to claim 19, wherein the touch electrodes are multiplexed as common electrodes, respectively.
